(19) United States
(12) Patent Application Publication
(10) Pub. No.: US 2011/0095813 A1
(43) Pub. Date: Apr. 28, 2011

(54) MOS TRANSISTOR RESISTOR, FILTER, AND INTEGRATED CIRCUIT

(75) Inventors: Masayuki OZASA, Kyoto (JP); Shigeo MASAI, Osaka (JP); Hitoshi KOBAYASHI, Osaka (JP); Shuya YAMASAKI, Osaka (JP)

(73) Assignee: PANASONIC CORPORATION, Osaka (JP)

(21) Appl. No.: 12/982,113

(22) Filed: Dec. 30, 2010

Related U.S. Application Data
(63) Continuation of application No. PCT/JP2009/003160, filed on Jul. 7, 2009.

(30) Foreign Application Priority Data
Jul. 11, 2008 (JP) 2008-181814

(51) Int. Cl. H03H 11/24

(52) U.S. Cl. 327/534

(57) ABSTRACT

A MOS transistor including a first MOS transistor M1 to be used as a resistor; an input voltage source 1 connected to the source of the first MOS transistor for applying an input voltage Vin; and a gate voltage source 6 connected to the gate of the first MOS transistor for applying a gate voltage Vg. The gate voltage Vg and the input voltage Vin are set within a range where a gate-source voltage and source-drain voltage of the first MOS transistor cause the first MOS transistor to operate in a non-saturation region and also are set to avoid the first MOS transistor operating in an operation region with leakage current. Fluctuations of the resistance value resulting from a change in leakage current due to manufacturing variations are reduced and favorable temperature characteristics are obtained.

### BACKGROUND OF INVENTION

1. Field of the Invention

The present invention relates to resistors utilizing MOS transistors, and particularly to a MOS transistor resistor suited for electronic devices that perform voice signal processing of a microphone, to signal processing of a sensor and to integrated circuits of the electronic devices.

2. Description of Related Art

Conventionally, it has been known to use MOS transistors as resistors. As an example of use of a MOS transistor resistor of such a type, FIG. 11 shows a voltage comparison circuit disclosed in JP S57-108670 A (page 3, FIG. 2).

The voltage comparison circuit is composed of a comparator 7, MOS transistors M5, M6 and a capacitor C. An input signal from a signal source Vsg is inputted through the capacitor C, and the MOS transistors M5, M6 are used as a resistor.

The operation of the resistor composed of the MOS transistors M5, M6 in the voltage comparison circuit will be described hereinafter. When a part of the resistor composed of the MOS transistor M5 in FIG. 11 is taken out, it can be illustrated as the configuration in FIG. 12. To compensate for the bidirectionality, the MOS transistor M6 is connected to the MOS transistor M5 in parallel, and the operation of the MOS transistor M6 is similar to that of the MOS transistor M5.

In FIG. 12, a current source 3 (current value I0) corresponds to a leakage current of the MOS transistor M5 in FIG. 11 and a high impedance input circuit 2 corresponds to the comparator 7 in FIG. 11.

Since a current and a gate-source voltage VGS are not supplied externally to the MOS transistor M5, the MOS transistor M5 is in an off state and operates in the weak-inversion (subthreshold) region.

A current value Isub in the weak-inversion region is expressed as follows (see Behzad Razavi, Design of Analog CMOS Integrated Circuit (McGRAW-HILL Publishing), p. 27, for example):

Isub=Isub0·exp(VGS/ζ·VT)) (1).

Here, Isub0 denotes a saturation current of the MOS transistor in the weak-inversion region. VT is given by kB·T/q and kB denotes a Boltzmann's constant. T denotes an absolute temperature and q denotes a quantity of electron charge. ζ denotes a weak-inversion coefficient.

A resistance value Rsub of the MOS transistor M5 is obtained by differentiating the current value Isub by the gate-source voltage VGS and inversing the resulting value, and the resistance value is expressed as follows:

Rsub=ζ·VT/Isub (2).

In the configuration of FIG. 12, Isub is a leakage current and it has an order of several PA in a semiconductor integrated circuit. When Isub=10 pA, ζ is about 1.1 and VT is 26 mV at a room temperature. Thus, for Rsub an extremely high resistance value of 2.86 GΩ can be achieved.

As a conventional example of a circuit using a MOS transistor resistor of such a type, FIG. 13 shows a filter circuit disclosed in Japanese Patent No. 3,497,022 (p. 5, FIG. 1). This filter circuit is composed of an operational amplifier 4, MOS transistors M17, M8, M9, M10, M11, a current source 8 (current I0), a current source 9 (current I1) and a capacitor C. The operation of the MOS transistor resistor used in the filter circuit will be described hereinafter.

When the section of the MOS transistor resistor in FIG. 13 is taken out, it corresponds to the circuit as shown in FIG. 14. In this circuit, input voltages are generated by the MOS transistor M11 and the current source 9. A buffer 5 and the high impedance input circuit 2 correspond to the operational amplifier 4 in FIG. 13.

Since the gate-source voltage VGS is given to the MOS transistor M7, the MOS transistor M7 is in an on state and it operates in the strong-inversion region. When the current of the MOS transistor M7 is substantially 0, the MOS transistor M7 operates in the non-saturation region (triode region).

A current value Itri in the non-saturation region is expressed as follows (see Behzad Razavi, Design of Analog CMOS Integrated Circuit (McGRAW-HILL Publishing), p. 27, for example):

Itri=k·(W/L)·((VGS−VTH)·VDS−VDS²/2) (3).

Here, k denotes a current amplification factor and it can be expressed as a product of a mobility μ and a gate capacity Cox of the MOS transistor. W denotes a gate width and L denotes a gate length. VTH denotes a threshold voltage and VDS denotes a drain-source voltage.

A resistance value Ron of the MOS transistor is obtained by differentiating the current value Itri by the drain-source voltage VDS and inversing the resulting value, and the resistance value is expressed as follows:

Ron=L/(k·W·(VGS−VDS−VTH)) (4).

In the configuration of FIG. 14, when the current of the MOS transistor M7 is substantially 0, the drain-source voltage VDS7 is approximately equal to 0V. The current amplification factor k, which is determined by the semiconductor process, is equal to about 100 μA/V². By selecting the current source 8 having a current value that makes the gate-source voltage VGS be VTH+0.1V and setting W7 and L7 to 1 μm and 100 μm, respectively, a high resistance value of 10 MΩ can be achieved.

IEEE, JOURNAL OF SOLID-STATE CIRCUITS (VOL. 38, NO. 6, JUNE 2003) also discloses in p. 958 and FIG. 1 a MOS transistor resistor that is used in a similar manner.

For the conventional MOS transistor resistors, however, the resistance values are determined by a leakage current and thus the resistance values fluctuate significantly due to manufacturing variations and temperature characteristics. For example, in the configuration shown in FIG. 12, since the MOS transistor M5 operates with the leakage current, the current value Isub changes significantly due to manufacturing variations. For example, a change in manufacturing batch can result in a change in leakage current to such a degree that the current value Isub changes by a single digit. As a result, the resistance value Rsub also changes by about a single digit.

When a filter is configured by using such a MOS transistor resistor, the cutoff frequency would change by a single digit due to the fluctuations resulting from manufacturing variations. With this, it is difficult to achieve a normal function as a filter.

Furthermore, the current value Isub changes significantly due to the temperature characteristics. For example, a change in temperature by 100° C. can result in a change in the current value by about an order of magnitude. Accordingly, the resistance value Rsub also changes by about an order of magnitude. FIG. 15 shows a change in the resistance value resulting from such temperature characteristics. The horizontal axis indicates the current I0 and the vertical axis indicates the resistance value Ron, and each of the current I0 and the resistance value Ron is expressed in a log scale. The broken curve A indicates a case of a low temperature, the solid curve B indicates a case of a room temperature and the alternate long and short dashed curve C indicates a case of a high temperature. As can be seen from the drawing, the resistance value Ron, which corresponds to the current value Isub in the non-saturation region, changes significantly in response to the temperature. When a filter is configured using such a resistance, the cutoff frequency changes by a single digit due to the change in the resistance value. Accordingly the effect of temperature characteristics is also a factor that poses difficulty in configuring a filter.

To solve the problems mentioned above, conditions under which a MOS transistor resistor can be operated in the non-saturation region and the effect of the temperature characteristics can be canceled will be investigated. For example, for the MOS transistor resistor shown in FIG. 14, the following case is assumed: the drain-source voltage VDS7 of the MOS transistor M7 that receives a small signal is approximately equal to 0 (VDS7≈0) and the gate-source voltage VGS7 is set in the non-saturation region. When gate-source voltages VGS8, VGS9, VGS11 of the MOS transistors M8, M9, M11 are substituted into Formula 4 to calculate the resistance value Ron in the above case, the resistance value is expressed as follows:

Ron=L7/(k·W7·(VGS8+VGS9−VGS11−VTH)) (5).

On the other hand, for the drain-source current IDS of the MOS transistor, a saturation current is expressed as follows:

IDS=(k/2)·(W/L)·(VGS−VTH)² (6).

To express the gate-source voltage VGS with the drain-source current IDS,

VGS=VTH+(IDS·(L/W)·(2/k))^{0.5} (7).

When each of the gate-source voltages VGS is substituted into Formula 5,

Ron=L7/((2·k)^{0.5}·W7·((I0·(L8/W8))^{0.5}+(I0·(L9/W9))^{0.5}−(I1·(L11/W11))^{0.5})) (8).

Temperature characteristics are determined by differentiating Formula 8 by temperature. Since the current amplification factor k is a function of the temperature,

∂Ron/∂T=(−½)·Ron/k·(∂k/∂T) (9).

Therefore, the conditions under which the effect of the temperature characteristics is canceled are Ron→0, in other words,

((I0·(L8/W8))^{0.5}+(I0·(L9/W9))^{0.5}−(I1·(L11/W11))^{0.5}))→∞ (10).

When this is substituted into Formula 8, the denominator becomes ∞ and Ron→0. That is, to achieve a resistance with less susceptibility to temperature characteristics in the non-saturation region, the resistance becomes small. FIG. 16 shows a change in the resistance value Ron relative to the current I0 in this case.

As can be seen from FIG. 16, a change in the resistance value due to the temperature characteristics is considerable even under the conditions where a resistance value with less susceptibility to temperature characteristics is obtained in the non-saturation region. For example, the larger a resistance value, the more advantageous it is to configure a filter to be incorporated into an integrated circuit. However, according to the characteristics shown in FIG. 16, the cutoff frequency changes significantly due to a change in the resistance value by the temperature when a filter is configured with an increased resistance value. Therefore, it becomes difficult to configure the filter.

### SUMMARY OF THE INVENTION

Therefore, with the foregoing in mind, it is an object of the present invention to provide a MOS transistor resistor with reduced fluctuations of the resistance value resulting from a change in leakage current due to manufacturing variations and with favorable temperature characteristics.

In order to solve the problem mentioned above, the MOS transistor resistor of the present invention includes: a first MOS transistor to be used as a resistor; an input voltage source connected to a source of the first MOS transistor for applying an input voltage Vin; and a gate voltage source connected to a gate of the first MOS transistor for applying a gate voltage Vg. The gate voltage Vg and the input voltage Vin are set within a range where a gate-source voltage and source-drain voltage of the first MOS transistor cause the MOS transistor to operate in a non-saturation region and also are set to avoid the first MOS transistor operating in an operation region with leakage current.

According to the present invention, the gate voltage Vg and the input voltage Vin are set in an appropriate manner to satisfy the conditions under which the first MOS transistor operates in the non-saturation region and the temperature characteristics of the resistance value become constant. As a result, fluctuations of the resistance value resulting from a change in leakage current are reduced and favorable temperature characteristics can be obtained.

### BRIEF DESCRIPTION OF THE DRAWINGS

FIG. 1 is a circuit diagram showing a MOS transistor resistor according to Embodiment 1 of the present invention.

FIG. 2 is a characteristic diagram showing the resistance value of the MOS transistor resistor.

FIG. 3 is a circuit diagram showing an applied example using the MOS transistor resistor.

FIG. 4 is a circuit diagram showing a primary high-pass filter using the MOS transistor resistor.

FIG. 5 is a circuit diagram showing a primary low-pass filter using the MOS transistor resistor.

FIG. 6 is a circuit diagram showing another exemplary configuration of the MOS transistor resistor according to Embodiment 1 of the present invention.

FIG. 7 is a circuit diagram showing yet another exemplary configuration of the MOS transistor resistor according to Embodiment 1 of the present invention.

FIG. 8 is a circuit diagram showing yet another exemplary configuration of the MOS transistor resistor according to Embodiment 1 of the present invention.

FIG. 9 is a circuit diagram showing yet another exemplary configuration of the MOS transistor resistor according to Embodiment 1 of the present invention.

FIG. 10 is a circuit diagram showing a MOS transistor resistor according to Embodiment 2 of the present invention.

FIG. 11 is a circuit diagram showing a voltage comparator using a conventional MOS transistor resistor.

FIG. 12 is a circuit diagram for explaining the operation of the conventional MOS transistor resistor.

FIG. 13 is a circuit diagram showing a filter circuit using a conventional MOS transistor resistor.

FIG. 14 is a circuit diagram for explaining the operation of the conventional MOS transistor resistor.

FIG. 15 is a characteristic diagram of the conventional MOS transistor resistor.

FIG. 16 is a characteristic diagram of another conventional MOS transistor resistor.

### DETAILED DESCRIPTION OF THE INVENTION

The MOS transistor resistor of the present invention, having the basic configuration as above, can be modified as follows.

That is, the MOS transistor resistor of the present invention further may include a second MOS transistor having the same polarity as the first MOS transistor. A gate and drain of the second MOS transistor are connected to the gate of the first MOS transistor, and a constant current is supplied to the second MOS transistor to make the second MOS transistor function as the gate voltage source.

Further, it is preferable that when a threshold voltage of the first MOS transistor is VTH, the gate voltage Vg and the input voltage Vin are set to satisfy substantially the following relationship: Vg=VTH+2·Vin.

Further, the source of the first MOS transistor may be grounded through the input voltage source. Further, the drain of the first MOS transistor may be connected to a high impedance input circuit. In that case, the high impedance input circuit may be an operational amplifier. Hereinafter, MOS transistor resistors according to embodiments of the present invention will be described with reference to the drawings.

### Embodiment 1

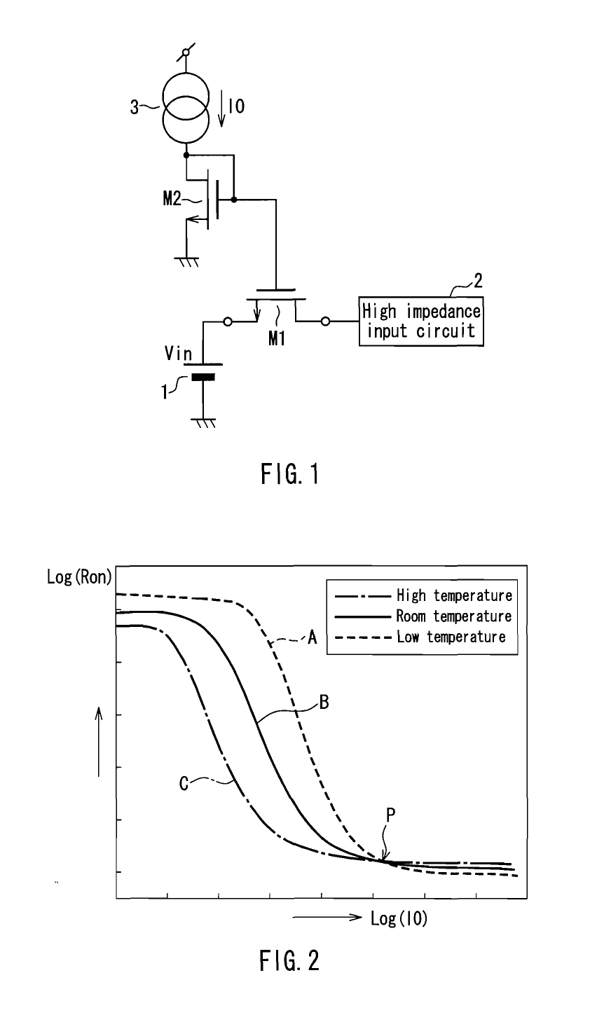

FIG. 1 is a circuit diagram showing a MOS transistor resistor according to Embodiment 1. This MOS transistor resistor is composed of MOS transistors M1, M2 and an input voltage source 1 (voltage Vin). As for the MOS transistor M1, its source is grounded through the input voltage source 1 and its drain is connected to a high impedance input (high input resistance) circuit 2 as a following stage circuit. To the gate of the MOS transistor M1, voltages generated by the MOS transistor M2 and the current source 3 (current I0) are applied.

The operation of the MOS transistor resistor configured as above will be described. Also for this MOS transistor resistor, the resistance value is expressed by the Formula 4. In the following description, the same symbols are used for elements that are similar to the formula elements that have been used to describe the prior art and are described with numerals related to the reference numerals of the MOS transistors corresponding thereto.

Ron=L1/(k·W1·(VGS1−VDS1−VTH)) (4).

Here, VDS1≈0 and VGS1=VGS2−Vin, where VGS1 and VGS2 denote gate-source voltages of the MOS transistor M1, M2, respectively, and VDS1 denotes the drain-source voltage of the MOS transistor M1. When Formula 7 is substituted into VGS2, it is expressed as follows:

Ron=L1/(k·W1·(I0·(L2/W2)·(2/k))^{0.5}−Vin)) (11).

The temperature characteristics are determined by differentiating Formula 11 by temperature. Since a current amplification factor k is a function of the temperature,

∂Ron/∂T=((−L1/W1)/((2·k·I0·(L2/W2))^{0.5}−Vin·k)²)·(((½)·I0·(L2/W2)/k)^{0.5}−Vin)·∂k/∂T (12).

Accordingly, the conditions under which the effect of the temperature characteristics is eliminated are ∂Ron/∂T=0, in other words, from Formula 12;

Vin=((½)·I0·(L2/W2)/k)^{0.5} (13).

When this is substituted into Formula 11,

Ron=(L1/W1)/(I0·(L2/W2)·k/2)^{0.5} (14).

Further, when the current I0 is determined from Formula 13,

I0=2k·(W2/L2)·Vin² (15).

When the gate-source voltage VGS2 is determined from Formulas 15 and 7,

VGS2=VTH+2·Vin (16).

This corresponds to the gate voltage Vg of the MOS transistor M1.

As can be seen from the above formula, when L1=1 μm, W1=100 μm, Vin=0.2V, L2=1 μm, W2=1 μm and k=100 μA/V², for example, the effect of the temperature characteristics is canceled if

I0=8 μm.

Further, in that case, the resistance value Ron becomes

Ron=2.88 MΩ.

Further, since VGS1=VGS2−Vin=1.1−0.2=0.9V, the operation in the non-saturation region is ensured with the voltage to be applied to VGS1 of the MOS transistor M1, whereby the operation in the operation region with leakage current is avoided.

FIG. 2 is a characteristic diagram showing the operation of the MOS transistor resistor according to Embodiment 1. On the graph, a point of intersection P where the curves A to C corresponding to the respective temperatures intersect corresponds to the resistance value Ron under the operation conditions under which the effect of the temperature characteristics is canceled.

As described above, the MOS transistor resistor according to the present embodiment includes the MOS transistor M1 to be used as a resistor, the input voltage source 1 connected to the source of the MOS transistor M1 for applying the input voltage Vin and the MOS transistor M2 that applies the gate-source voltage VGS2 to the gate of the MOS transistor M1. The gate and drain of the MOS transistor M2 are connected to the gate of the MOS transistor M1. By supplying the constant voltage I0 to the MOS transistor M2, the voltage VGS2 is supplied.

The gate-source voltage VGS2 and the input voltage Vin are set within a range where the gate-source voltage and source-drain voltage of the MOS transistor M1 cause the MOS transistor M1 to operate in the non-saturation region and are also set to have a relationship that satisfies conditions under which the temperature characteristics of resistance value of the first MOS transistor M1 become constant. As a result, the operation of the MOS transistor M1 becomes the operation in the non-saturation region, so that the effect of a leakage current is reduced and the operation with the effect of the temperature characteristics being suppressed can be achieved.

In the above description, the back-gate effect (body effect) of the MOS transistors is not taken into consideration at the time of investigating the MOS transistor resistor according to the present embodiment. By selecting a small value for the voltage Vin of the input voltage source 1, the back-gate effect be sufficiently small so that it can be ignored as a practical matter.

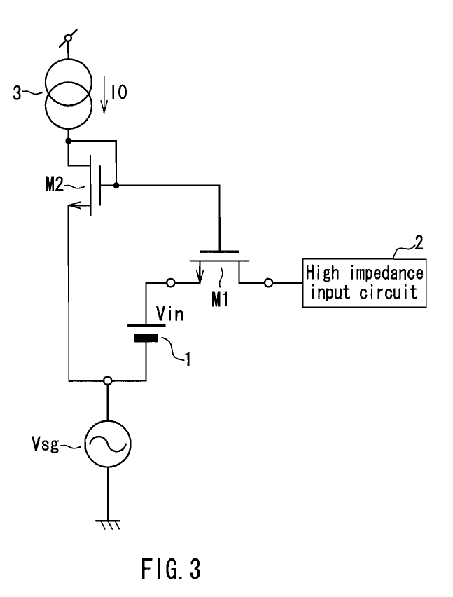

For the MOS transistor resistor having the configuration of FIG. 1, the effect of the signal source Vsg on the resistance value Ron can be reduced by connecting the signal source Vsg to the sources of the MOS transistors M1, M2 in common as shown in FIG. 3.

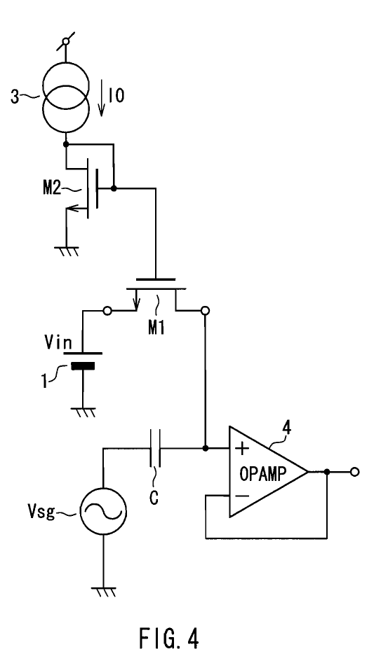

FIG. 4 shows an example where the MOS transistor resistor according to the present embodiment is applied to a filter as a primary high-pass filter. The MOS transistor resistor having the configuration shown in FIG. 1 is connected to the noninverting input terminal of the operational amplifier 4 and the signal source Vsg also is connected to the noninverting input terminal through the capacitor C. The CR high-pass filter is formed by the capacitor C connected in series to the signal source Vsg and the MOS transistor M1 connected in parallel to the signal source Vsg. As in this example, by using the MOS transistor resistor according to the present embodiment together with the capacitor C that can be incorporated into an integrated circuit, a filter with small temperature characteristics can be configured on an integrated circuit.

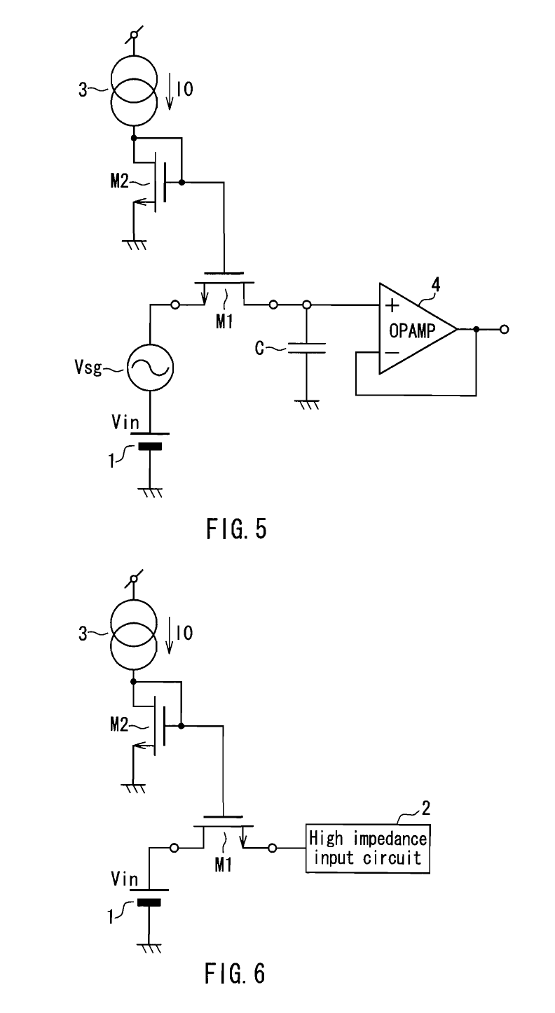

FIG. 5 shows an example where the MOS transistor resistor according to the present embodiment is applied to a primary low-pass filter. The CR low-pass filter is formed by the MOS transistor M1 connected in series to the signal source Vsg and the capacitor C connected in parallel to the signal source Vsg.

FIG. 6 shows a configuration in which the connections of the source and drain of the MOS transistor M1 are reversed in contrast to the configuration of FIG. 1. In this way, because of the bidirectionality of the source and drain, the MOS transistor M1 can be used in the present embodiment by connecting the source and drain in reverse.

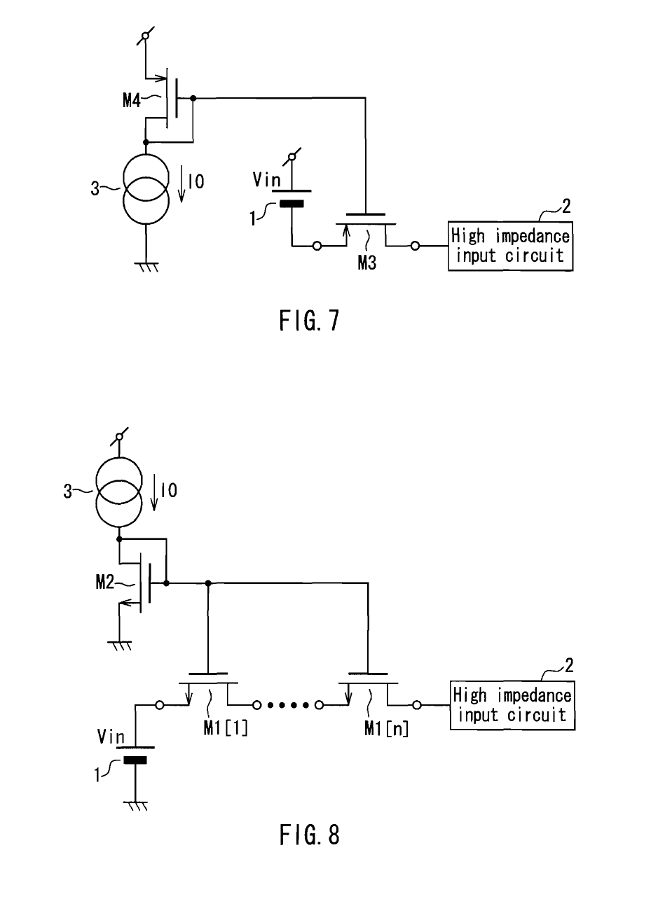

FIG. 7 shows a case where the n-channel MOS transistors M1, M2 in the MOS transistor resistor of FIG. 1 are replaced with p-channel MOS transistors M3, M4. In this way, similar effects can be achieved even if the MOS transistor resistor is configured using p-channel MOS transistors.

FIG. 8 shows a configuration in which the MOS transistor M1 of FIG. 1 is replaced with a plurality of MOS transistors M1[1] to M1[n] that are connected in series to each other. In this way, by connecting in series the MOS transistors M1, a larger resistance value can be obtained.

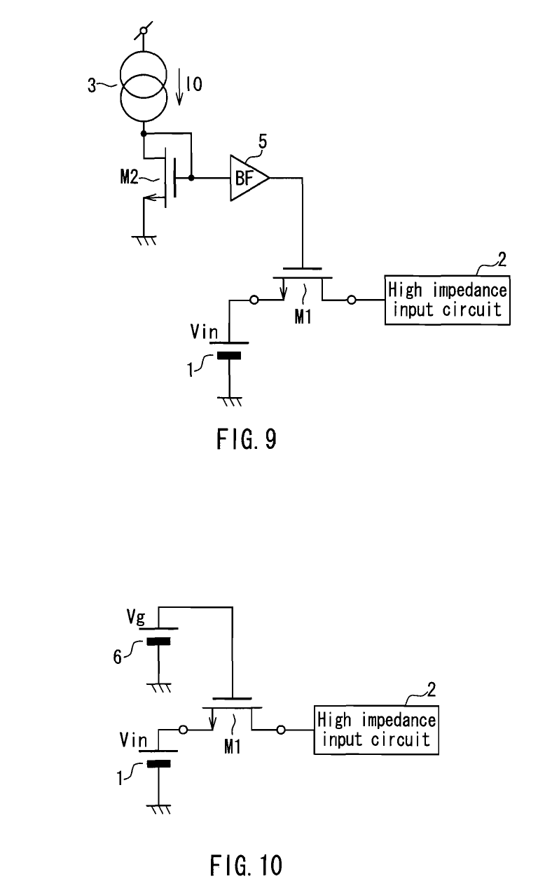

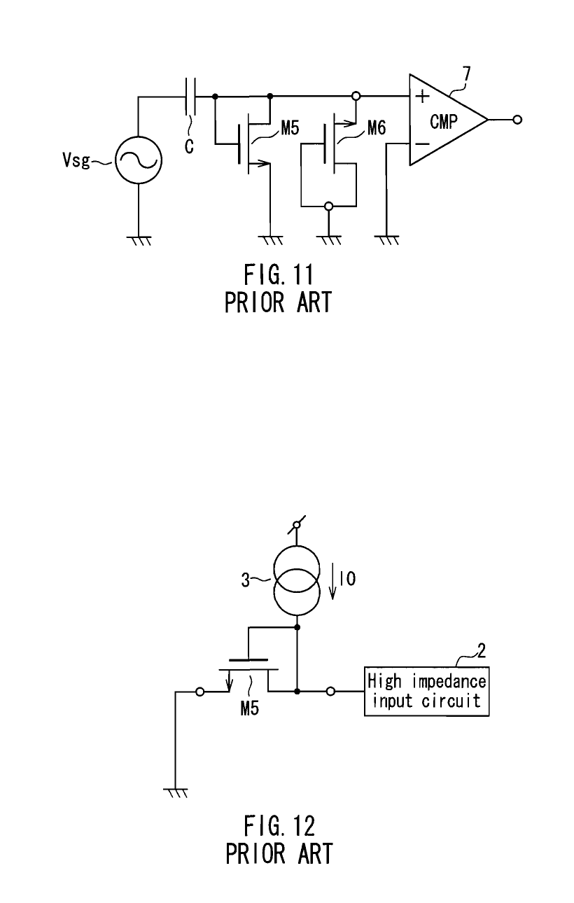

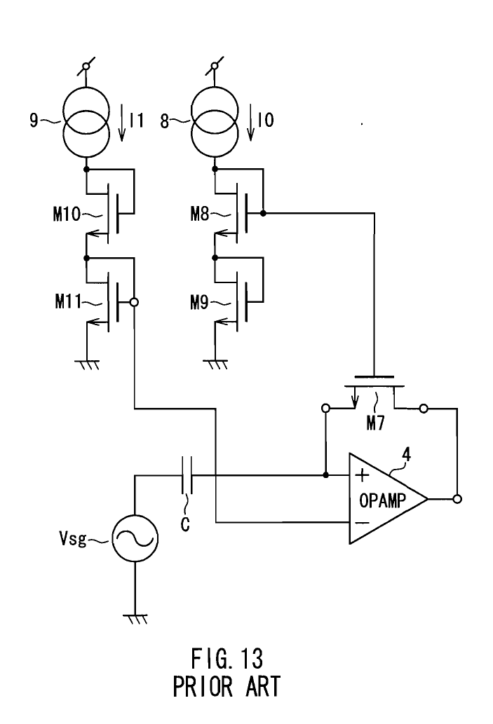

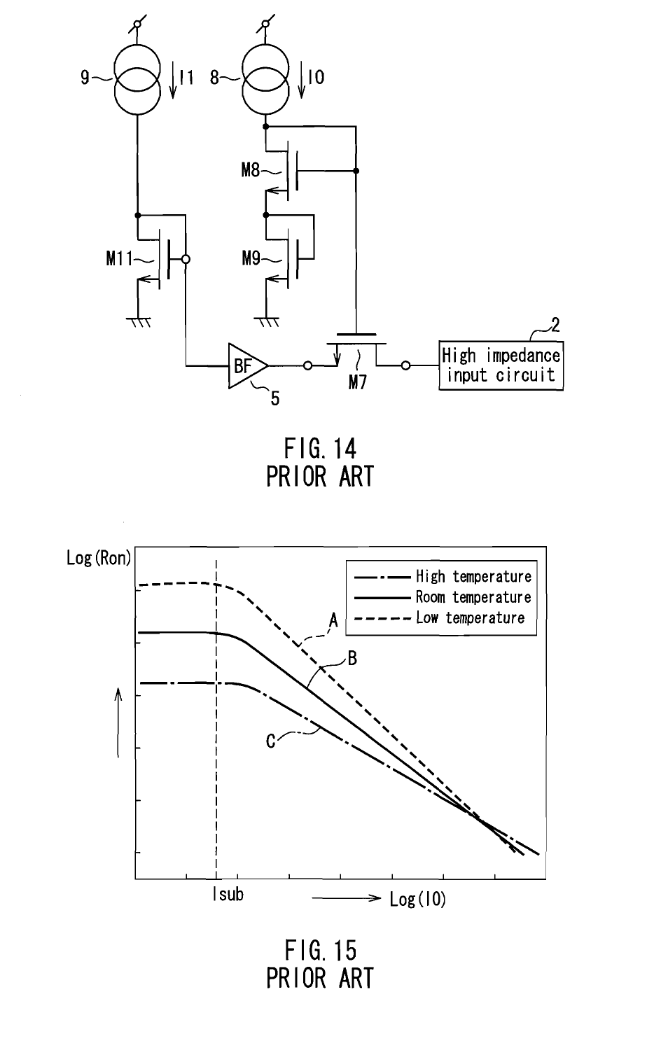

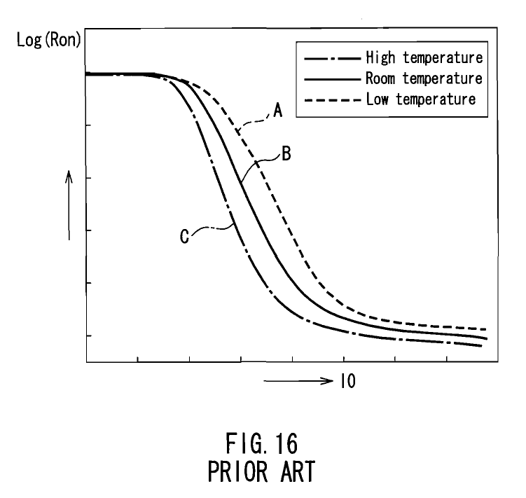

As shown in FIG. 9, in the MOS transistor resistor shown in FIG. 1, the gate-source voltage VGS2 of the MOS transistor M2 may be applied to the gate of the MOS transistor M1 through the buffer 5.

### Embodiment 2

FIG. 10 is a circuit diagram showing a MOS transistor resistor according to Embodiment 2 of the present invention. This MOS transistor resistor is different from the configuration of the MOS transistor resistor according to Embodiment 1 shown in FIG. 1 in that the MOS transistor M2 is replaced with a gate voltage source 6 (voltage Vg). That is, a voltage Vg of the gate voltage source 6 is applied to the gate of the MOS transistor M1.

In the configuration of FIG. 10. by setting the voltage Vg to the same voltage as the gate-source voltage VGS2 of the MOS transistor M2 of FIG. 1, the exact same effects as those achieved by the MOS transistor resistor according to Embodiment 1 can be achieved. That is, by setting the gate voltage Vg to the gate-source voltage VGS2 that is expressed by Formula 16, in other words, to a voltage obtained by adding to the threshold voltage VTH the input voltage Vin×2, the temperature characteristics of the resistance value Ron can be canceled.

As described above, the MOS transistor resistor according to the present embodiment includes the MOS transistor M1 to be used as a resistor, the input voltage source 1 connected to the source of the MOS transistor M1 for applying an input voltage Vin, and the gate voltage source 6 connected to the gate of the MOS transistor M1 for applying the gate voltage Vg. The gate voltage Vg and the input voltage Vin are set to have a relationship similar to that between the voltage VGS2 and the input voltage Vin in Embodiment 1. Consequently, the operation of the MOS transistor M1 becomes the operation in the non-saturation region, and as a result, the effect of a leakage current is reduced and the operation with the effect of the temperature characteristics being suppressed can be achieved.

According to the MOS transistor resistor of the present invention, the resistance value of the MOS transistor is not susceptible to the effect of a leakage current and the operation that wards off temperature characteristics can be achieved. Thus, the MOS transistor resistor of the present invention is useful for an integrated circuit including a filter circuit and is also useful for voice signal processing performed by such as a microphone and for integrated circuits of electronic devices including a sensor that perform signal processing.

The invention may be embodied in other forms without departing from the spirit of essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A MOS transistor resistor comprising:
a first MOS transistor to be used as a resistor;
an input voltage source connected to a source of the first MOS transistor for applying an input voltage Vin; and
a gate voltage source connected to a gate of the first MOS transistor for applying a gate voltage Vg,
wherein the gate voltage Vg and the input voltage Vin are set within a range where a gate-source voltage and source-drain voltage of the first MOS transistor cause the MOS transistor to operate in a non-saturation region and also are set to avoid the first MOS transistor operating in an operation region with leakage current.

2. The MOS transistor resistor according to claim 1, further comprising a second MOS transistor having the same polarity as the first MOS transistor.
wherein a gate and drain of the second MOS transistor are connected to the gate of the first MOS transistor, and a constant current is supplied to the second MOS transistor to make the second MOS transistor function as the gate voltage source.

3. The MOS transistor resistor according to claim 1, wherein when a threshold voltage of the first MOS transistor is VTH, the gate voltage Vg and the input voltage Vin are set to satisfy substantially the following relationship:
Vg=VTH+2·Vin.

4. The MOS transistor resistor according to claim 1, wherein the source of the first MOS transistor is grounded through the input voltage source.

5. The MOS transistor resistor according to claim 1, wherein the drain of the first MOS transistor is connected to a high impedance input circuit.

6. The MOS transistor resistor according to claim 5, wherein the high impedance input circuit is an operational amplifier.
